(19) United States
(12) Patent Application Publication
(10) Pub. No.: US 2005/0174039 A1
(43) Pub. Date: Aug. 11, 2005

(54) Display panel and method for manufacturing display panel

(76) Inventors: Ryuji Nishikawa, Gifu-shi (JP); Tetsuji Omura, Ogaki-shi (JP)

Correspondence Address: MCCARTER & ENGLISH LLP;CITYPLACE I, 185 ASYLUM STREET, HARTFORD, CT, 06103, US

(21) Appl. No.: 11/040,614

(22) Filed: Jan. 18, 2005

(30) Foreign Application Priority Data
Jan. 20, 2004 (JP) 2004-12457

(51) Int. Cl. H01J 1/62; H01J 9/26

(52) U.S. Cl. 313/495; 445/25

(57) ABSTRACT

A sealing substrate and an EL substrate are placed opposing each other with a predetermined gap therebetween. A nontransparent region is formed in a peripheral portion of the sealing substrate in advance. The nontransparent region is irradiated with laser through the EL substrate so that the nontransparent region is heated and glass is elevated and welded. Because portions of the sealing substrate other than the nontransparent region are clear, it is possible to realize a top emission type structure.

### CROSS-REFERENCE TO RELATED APPLICATIONS

The entire disclosure of Japanese Patent Application No. 2004-12457 including specification, claims, drawings and abstract is incorporated herein by reference.

### BACKGROUND OF THE INVENTION

1. Field of the Invention

The present invention relates to manufacture of a display panel such as an organic electroluminescence (hereinafter simply referred to as “EL”) display panel and, in particular, to a sealing structure in the display panel.

2. Description of the Related Art

Plasma display panels (PDP) and liquid crystal display devices (LCD) are becoming widely available as thin flat display panels and organic EL panels are commercially available.

In an organic EL panel, an organic material is used as a light emitting material in each pixel or the like. Because the lifetime of the organic material is shortened when the organic material contains moisture, it is necessary to minimize an amount of moisture in a space in which the pixel is present. For this purpose, a sealing substrate is disposed to oppose, with a predetermined gap, an EL substrate on which display pixels including EL elements are formed in a matrix form and the peripheral portion of the substrates is air-tightly sealed with a sealing material made of a resin to prevent moisture from intruding into the inside. In addition, a desiccant is provided in the inside space to remove moisture.

As the sealing material, an epoxy-based ultraviolet curable resin or the like is used. However, there is a demand for further improving the air-tightness.

Normally, a glass substrate is used as the EL substrate and as the sealing substrate. For joining glass structures, there is a method for fusing the glass through heating and joining the glass structures. It can be considered that sealing with a higher air tightness than the sealing with a resin sealing material can be realized using this sealing process of glass. In particular, it may be possible to join the peripheral portions of glass substrates through welding of glass using laser light. Joining of glass using laser light is disclosed in, for example, Japanese Patent Laid-Open Publication No. 2003-170290.

In the process described in Japanese Patent Laid-Open Publication No. 2003-170290, an absorbing structure layer which absorbs laser is formed on the surface of glass. This reference also proposes doping of an impurity into glass through impurity doping and welding of the glass which is thus made nontransparent by laser irradiation. In the method of using the nontransparent glass, however, the entire nontransparent glass does not allow the light to transmit.

### SUMMARY OF THE INVENTION

According to the present invention, a pixel substrate and a sealing substrate are joined through sealing by welding using laser irradiation. Therefore, sealing can be reliably achieved with a small area and an area of a display region in which the display can be actually realized can be increased. As a consequence, the size of the display can be reduced. In addition, because the joining is achieved by welding, it is possible to reliably prevent moisture from intruding and to reduce the amount of desiccant to be sealed inside or to omit such a desiccant. Moreover, because a region of the absorbing structure to be used in the welding can be limited to a portion in which the welding actually takes place, it is possible to leave the region of the sealing substrate corresponding to the display region transparent. Therefore, it is possible to emit light through the sealing substrate to realize a top emission type pixel on the pixel substrate. By employing a top emission type structure, it is possible to increase an aperture ratio (a ratio of area of light emission region in a pixel) and to achieve a bright display.

Furthermore, by using the region of absorbing structure formed on the sealing substrate as a black matrix, it is possible to easily form the black matrix. In this case, the sealing portion may be formed by an adhesive.

### BRIEF DESCRIPTION OF THE DRAWINGS

A preferred embodiment of the present invention will be described in detail based on the following drawings, wherein:

FIG. 1 is a diagram showing laser irradiation;

FIG. 2 is a diagram showing a structure of a sealing substrate;

FIG. 3 is a diagram showing a sealing substrate on which a black matrix is formed;

FIG. 4 is a diagram showing a structure of a pixel;

FIG. 5 is a diagram showing a circuit structure;

FIG. 6 is a diagram showing a structure of an EL substrate having a terminal portion;

FIG. 7 is a diagram showing laser irradiation with respect to the terminal portion;

FIG. 8 is a diagram schematically showing a circuit structure on an EL substrate; and

FIG. 9 is a diagram showing an example structure of a terminal portion.

### DESCRIPTION OF PREFERRED EMBODIMENT

A preferred embodiment (hereinafter, referred to simply as “embodiment”) of the present invention will now be described referring to the drawings.

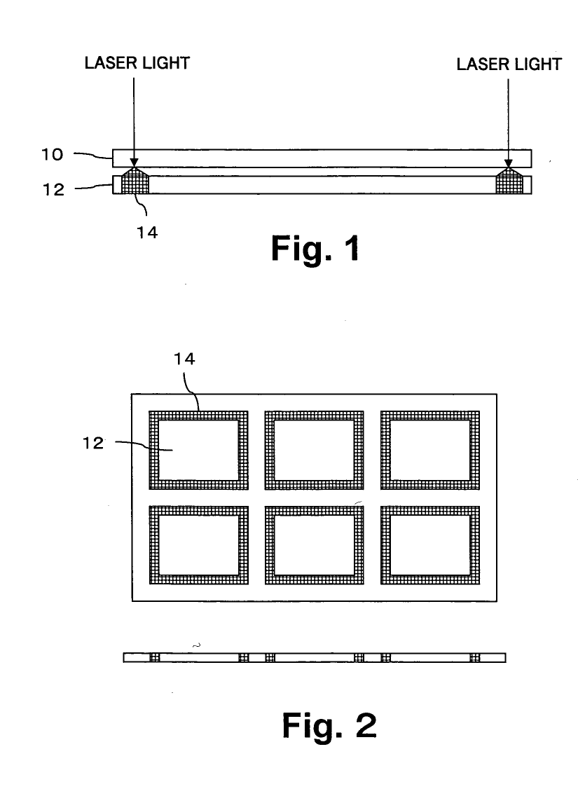

FIGS. 1 and 2 show joining of substrates according to a preferred embodiment of the present invention. An EL substrate 10 which is a pixel substrate on which a pixel or pixels are formed and a sealing substrate 12 for sealing an upper surface of the EL substrate 10 are placed opposing each other. The sealing substrate 12 has an absorbing structure region which absorbs laser such as a nontransparent glass in the portion to be sealed by welding. For example, the sealing substrate 12 can be made nontransparent by doping a metal though an ion injection or ion exchange method, for example, and a nontransparent region 14 which functions as an absorbing structure region which absorbs laser light is formed. In the ion exchange method, a resist which is patterned so as to expose the portion to become a nontransparent region is formed on the sealing substrate 12 and the structure is immersed in a solution containing a predetermined metal to exchange the ions in the sealing substrate 12 (for example, sodium) to diffuse the metal into the sealing substrate 12. In any method, as shown in the drawings, although it is possible to form the entire thickness of the sealing substrate 12 to be nontransparent, it is also possible to form only the surface portion of the sealing substrate 12 within a predetermined depth from the surface to be nontransparent.

It is also possible to form the nontransparent region 14 which functions as an absorbing structure region on the sealing substrate 12. For example, it is possible to form a groove in a region of the sealing substrate 12 on which the nontransparent region 14 is to be formed and layer a nontransparent material such as a metal in the groove through, for example, vacuum evaporation, CVD (Chemical Vapor Deposition), or sputtering, or to apply a colored paint to form the nontransparent region 14.

In the present embodiment, copper is used as the metal to be used in the absorbing structure, but the present invention is not limited to copper and other nontransparent metals such as silver, iron, etc. may be used. An optical transmissivity of the nontransparent region 14 is, for example, preferably approximately 1%-2% for light having a wavelength of 550 nm. When the optical transmissivity is 8% or greater, an amount of absorption of light is small and the portion to be heated cannot be heated to a sufficient degree.

The EL substrate 10 and the sealing substrate 12 are then fixed with a gap of 6 μm-10 μm, more preferably, approximately 8 μm therebetween and laser light is irradiated from the side of the EL substrate 10 in this state. When the laser is a YAG laser (1064 nm), a power of approximately 10 W to 50 W is employed.

With this process, light is absorbed in the nontransparent region 14 of the sealing substrate 12 and this region is fused through heating. It is preferable that the nontransparent region 14 is heated to a temperature of approximately 600° C. to 700° C. With this process, the nontransparent region 14 is fused and this portion is elevated. The tip of the nontransparent region 14 contacts the EL substrate 10 and is welded. Typically, a laser light of a spot shape is used and the nontransparent region is scanned with the spot so that the EL substrate 10 and the sealing substrate 12 are sealed at their peripheral portions through welding.

In this manner, the EL substrate 10 and the sealing substrate 12 can be welded through glass welding using laser light. With the laser irradiation, because only the portion to be welded is heated and the internal space created by the sealing process is heated to only a small extent, the temperatures of the internal space and the temperature of the external space do not significantly change. Therefore, it is easy to set the pressure inside the internal space after sealing to an appropriate value. In addition, because the sealing process is executed in a nitrogen atmosphere which has substantially no moisture and the sealing by glass welding results in a very high degree of air tightness, the probability of moisture intruding into the internal space is low during use in an atmosphere after the substrates are sealed. Thus, it is not necessary to provide a desiccant in the internal space, and, even if a desiccant is provided, the amount of the desiccant can be significantly reduced. Moreover, when the glass welding process using laser light is employed, the width of the joining portion between the EL substrate 10 and the sealing substrate 12 is small. Therefore, it is possible to reduce an area of the sealing region at the peripheral portion of the EL substrate and to reduce the size of the display panel.

In the present embodiment, the nontransparent region 14 on the sealing substrate 12 is provided only in the peripheral portion of the sealing substrate 12 and the portion of the sealing substrate 12 corresponding to the display region of the EL substrate 10 is transparent. Therefore, it is possible to emit light through the sealing substrate 12 and to realize a top emission type display panel.

FIG. 2 shows a state in which a plurality (in the illustrated configuration, 6) of sealing substrates 12 are provided on one glass substrate. As illustrated, nontransparent regions 14 having a rectangular frame shape are formed on a glass substrate with a predetermined spacing. Similarly, a plurality of EL substrates 10 are formed over the glass substrate. The structure is fixed and then separated into each separate display panel by a laser cutter. In this manner, a plurality of EL substrates 10 can be manufactured together in the same steps, which allows for effective process of affixing and cutting, each as one step.

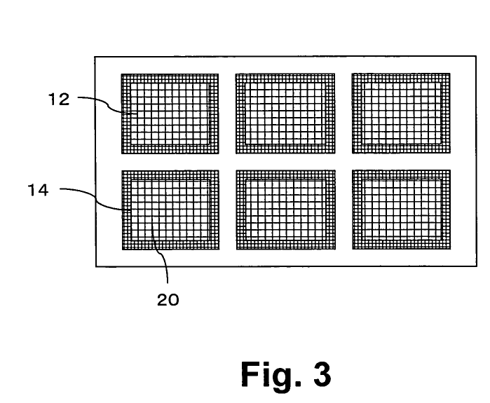

FIG. 3 is a diagram showing a configuration in which the nontransparent region 14 is also used as a black matrix in an unnecessary region of each pixel in the display region. As shown, in this configuration, the black matrix 20 is formed in a similar manner to that of the nontransparent region 14 and corresponding to the boundaries of the pixels formed on the EL substrate 10. With this structure, the distinction between pixels is clear and a clearer display can be realized. In addition, because the black matrix 20 can be formed along with the nontransparent region 14 when the nontransparent region 14 is formed, it is not necessary to add new steps.

It is also preferable to use the method of the present embodiment to form the black matrix in a normal substrate which does not use the nontransparent region 14. In this case, the sealing can be effected using a resin or the like.

As described, in the present embodiment, a glass substrate is used as the EL substrate 10 and as the sealing substrate 12. However, the material of the substrates is not limited to glass as long as the sealing substrate 12 or the absorbing structure formed on the sealing substrate 12 absorbs laser and welding by the laser energy is enabled. For example, it is possible to use various resin films or metal films as the substrate.

In the present embodiment, an absorbing structure region is formed in the peripheral region of the sealing substrate 12, but it is also possible to alternatively provide the absorbing structure region in the peripheral region of the EL substrate 10. In this case, in addition to the region of the sealing substrate 12 opposing the pixel region, the peripheral region of the sealing substrate 12 to be irradiated with laser must also be transparent to allow laser to transmit.

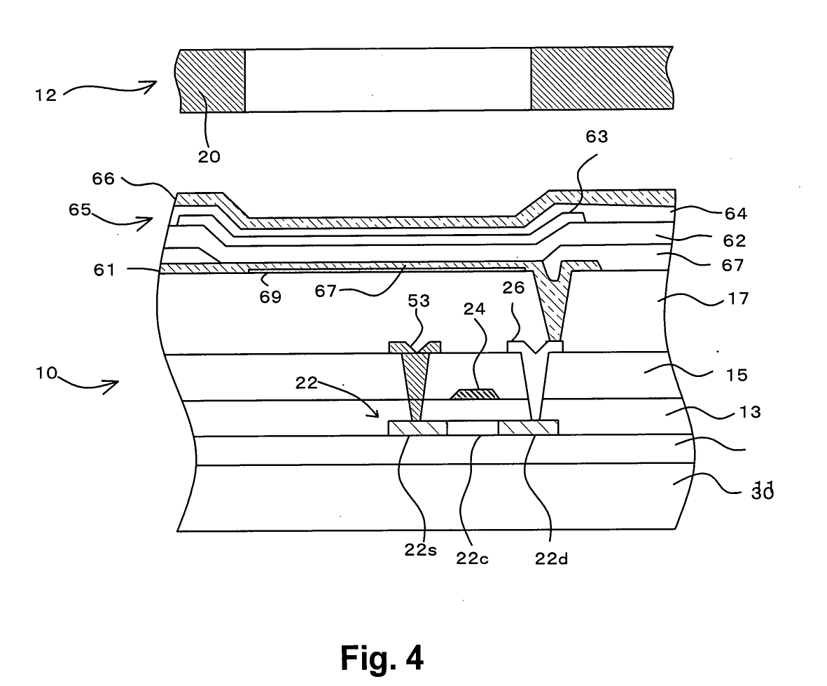

FIG. 4 is a cross sectional diagram showing a structure of a portion of a light emitting region and a driver TFT within one pixel. A plurality of TFTs are provided in each pixel. A driver TFT is a TFT which controls a current to be supplied from a power supply line to an organic EL element. A buffer layer 11 having a layered structure of SiN and SiO₂ is formed over the entire surface of the glass substrate 30 and a polysilicon active layer 22 is formed on the buffer layer 11 in a predetermined area (area in which a TFT is to be formed).

A gate insulating film 13 is formed over the entire surface covering the active layer 22 and the buffer layer 11. The gate insulating film 13 is formed by, for example, layering SiO₂ and SiN. A gate electrode 24 made of, for example, Cr is formed above the gate insulating film 13 in positions above a channel region 22c. Using the gate electrode 24 as a mask, impurities are doped into the active layer 22 so that a channel region 22c in which no impurity is doped is formed in the active layer 22 below the gate electrode which is at the center and a source region 22s and a drain region 22d which are doped with the impurities are formed in the active layer 22 on both sides of the channel region 22c.

An interlayer insulating film 15 is formed over the entire surface covering the gate insulating film 13 and the gate electrode 24, a contact hole is formed through the interlayer insulating film 15 in positions above the source region 22s and the drain region 22d, and a source electrode 53 and a drain electrode 26 to be placed on an upper surface of the interlayer insulating film 15 are formed through the contact hole. A power supply line (not shown) is connected to the source electrode 53. In the illustrated configuration, the driver TFT formed in this manner is a p-channel TFT, but the driver TFT may alternatively be an n-channel TFT.

A planarizing film 17 is formed over the entire surface covering the interlayer insulating film 15, source electrode 53, and drain electrode 26. A reflective film 69 made of Ag or the like is provided on an upper surface of the planarizing film 17 at a position corresponding to the light emitting region and a transparent electrode 61 which functions as an anode is provided on the reflective film 69. A contact hole is formed through the planarizing film 17 above the drain electrode 26, and the drain electrode 26 and transparent electrode 61 are connected through the contact hole.

Normally, SiO₂ or SiN is used for the interlayer insulating film 15 and an acrylic resin or the like is used for the planarizing film 17. It is also possible to use TEOS or the like. The source electrode 53 and drain electrode 26 are made of a metal such as aluminum, and, normally, ITO is used for the transparent electrode 61.

Typically, the transparent electrode 61 is formed in a large portion of each pixel and has an overall shape of an approximate rectangle. A contact portion for connection to the drain electrode 26 is formed as a protruding section which extends into the contact hole. The reflective film 69 is formed in a size slightly smaller than the transparent electrode 61.

An organic layer 65 having a hole transport layer 62 which is formed over the entire surface, an organic light emitting layer 63 which is formed in a size slightly larger than the light emitting region, and an electron transport layer 64 which is formed over the entire surface is formed above the transparent substrate 61. An opposing electrode 66 which is transparent (such as ITO) and formed over the entire surface is formed above the organic layer 65 as a cathode.

A planarizing film 67 is formed on a peripheral portion of the transparent electrode 61 and below the hole transport layer 62 so that the light emitting region of each pixel is limited to a portion above the transparent electrode 61 and in which the hole transport layer 62 is directly in contact with the transparent electrode 61. Typically, an acrylic resin or the like is used for the planarizing film 67, but it is also possible to use TEOS or the like.

For the hole transport layer 62, organic light emitting layer 63, and electron transport layer 64, materials which are typically used for an organic EL element are used and the light emission color is determined corresponding to the material (normally, a dopant) in the organic light emitting layer 63. For example, NPB or the like is used for the hole transport layer 62, TBADN+DCJTB or the like is used for the organic light emitting layer 63 of red color, Alq₃+CFDMQA or the like is used for the organic light emitting layer 63 of green color, TBADN+TBP or the like is used for the organic light emitting layer 63 of blue color, and Alq₃ or the like is used for the electron transport layer 64.

In this structure, when the driver TFT is switched on corresponding to a voltage which is set on the gate electrode 24, a current from the power supply line flows from the transparent electrode 61 to the opposing electrode 66, and light emission is achieved in the organic light emitting layer 63 due to the current. The light transmits through the opposing electrode 66, is reflected by the reflective film 69, and is emitted toward top of FIG. 4.

A black matrix 20 is provided opposing a portion of the sealing substrate 12 other than the portion corresponding to the light emitting region of each pixel on the EL substrate 10. Therefore, it is possible to effectively prevent unclear display due to mixture of light from the light emitting region of an adjacent pixel.

By employing a top emission type structure, it is possible to also form a light emitting region above the TFT, and therefore, it is possible to easily form a bright panel with a high aperture ratio (percentage of light emitting region) even when a pixel circuit having a plurality of TFTs is used.

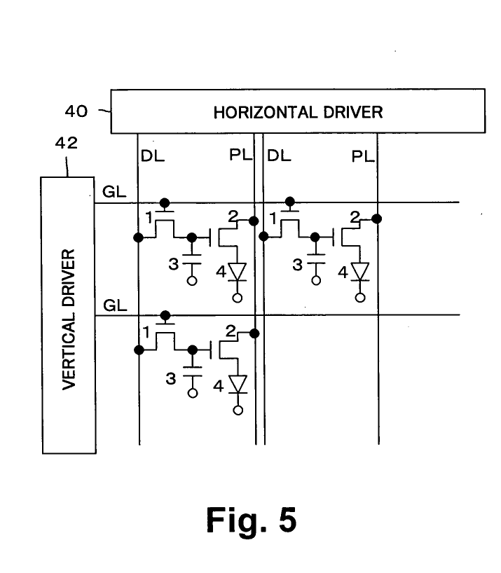

FIG. 5 schematically shows a structure of a circuit on the EL substrate 10. A horizontal driver 40 and a vertical driver 42 are provided as peripheral circuits and the internal region forms the display region. A data line DL and a power supply line PL are provided from the horizontal driver 40 along a vertical direction corresponding to pixels of each column and a gate line GL is provided from the vertical driver 42 along the horizontal direction corresponding to pixels of each row. A power supply voltage, an operation clock, and video data are supplied to the horizontal driver 40 and vertical driver 42 from external devices through an interface.

Each pixel comprises an n-channel selection TFT 1, a p-channel driver TFT 2, a storage capacitor 3, and an organic EL element 4. A drain of the selection TFT 1 is connected to a data line DL, a gate of the selection TFT 1 is connected to a gate line GL, and a source of the selection TFT 1 is connected to a gate of the driver TFT 2. One terminal of the storage capacitor 3 is connected to the gate of the driver TFT 2 and the other terminal of the storage capacitor 3 is connected to an SC capacitor line having a predetermined potential. A source of the driver TFT 2 is connected to a power supply line PL and a drain of the driver TFT 2 is connected to an anode of the organic EL element 4. A cathode of the organic EL element 4 is connected to a cathode power supply having a low voltage.

When the gate line GL is set to H, the selection TFT 1 on the corresponding row is switched on. In this state, when a data voltage is set on the data line DL, the data voltage is stored in the storage capacitor 3, the driver TFT 2 allows a current corresponding to the data voltage to flow from the power supply line PL through the organic EL element 4, and light is emitted corresponding to the data voltage.

When a top emission type structure as shown in FIGS. 3 and 4 is employed, the selection TFT 1, driver TFT 2, and various lines can be formed below the pixel region and a clear display can be maintained by the black matrix 20.

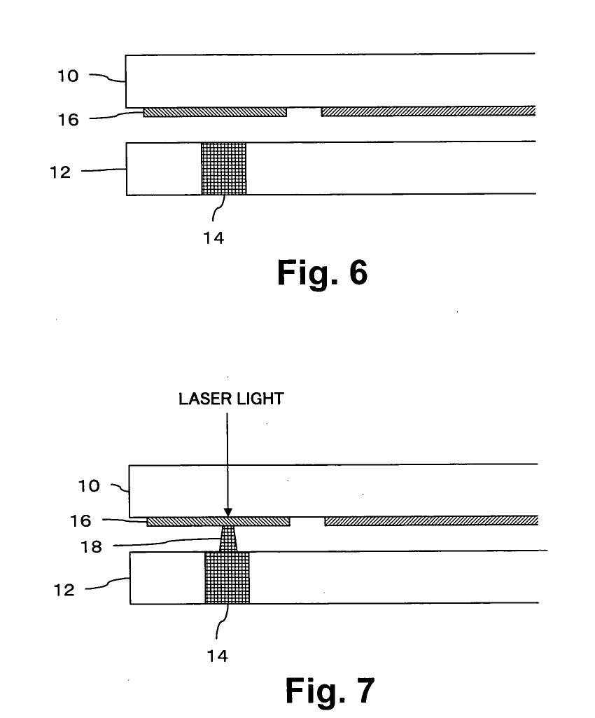

A large portion of the EL substrate 10 is dedicated as a display region in which display pixels are disposed in a matrix form and a driver or the like is disposed in the peripheral portion. As shown in FIG. 6, a terminal portion 16 for connection with the external device is provided because a video signal, power supply, etc. are supplied from the outside. The terminal portion 16 comprises a plurality of pad portions for connection to the outside and a plurality of line portions for electrical connection with the internal circuit are connected to the pad portions.

The pads and the line portions to be connected to the pads in the terminal portion 16 are normally formed of a metal such as aluminum, but the portion of the pads and line portions in the terminal portion 16 which must allow laser to transmit is made of ITO, which is a transparent conductor.

Therefore, as shown in FIG. 7, in the terminal portion 16 also, the sealing substrate 12 is irradiated with the laser light through the EL substrate 10, the laser irradiated region is heated, the sealing portion 18 is elevated, and the substrates 10 and 12 are sealed through glass welding.

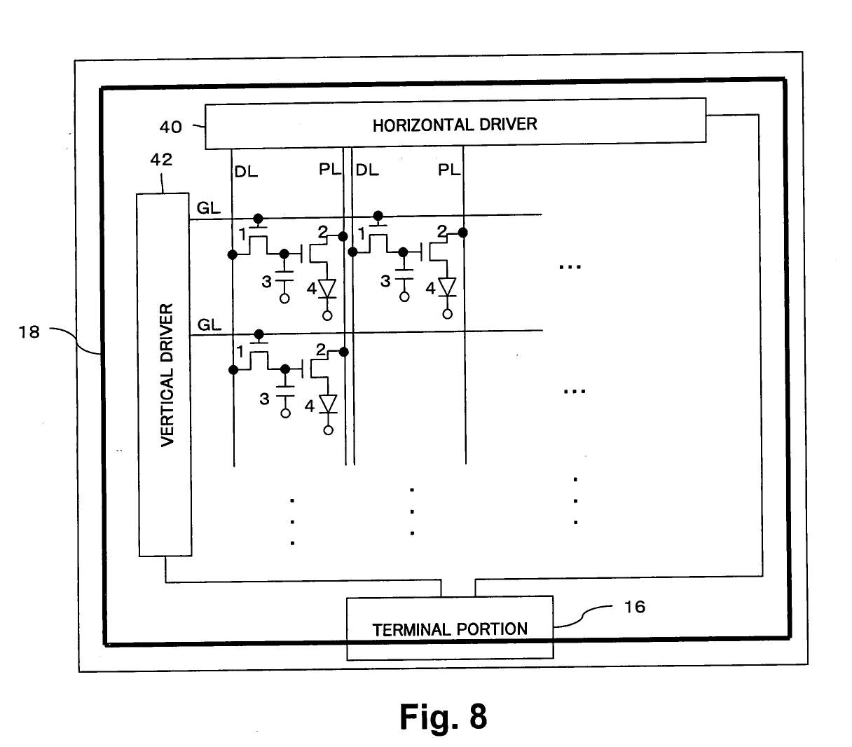

FIG. 8 schematically shows a structure of a circuit on the EL substrate 10. A horizontal driver 40 and a vertical driver 42 are provided as peripheral circuits and the internal region forms the display region. A data line DL and a power supply line PL are provided from the horizontal driver 40 along a vertical direction corresponding to pixels of each column and a gate line GL is provided from the vertical driver 42 along the horizontal direction corresponding to pixels of each row. A power supply voltage, an operation clock, and video data are supplied to the horizontal driver 40 and vertical driver 42 from external devices through a terminal portion.

Each pixel comprises an n-channel selection TFT 1, a p-channel driver TFT 2, a storage capacitor 3, and an organic EL element 4. A drain of the selection TFT 1 is connected to a data line DL, a gate of the selection TFT 1 is connected to a gate line GL, and a source of the selection TFT 1 is connected to a gate of the driver TFT 2. One terminal of the storage capacitor 3 is connected to the gate of the driver TFT 2 and the other terminal of the storage capacitor 3 is connected to an SC capacitor line having a predetermined potential. A source of the driver TFT 2 is connected to a power supply line PL and a drain of the driver TFT 2 is connected to an anode of the organic EL element 4. A cathode of the organic EL element 4 is connected to a cathode power supply having a low voltage.

When the gate line GL is set to H, the selection TFT 1 on the corresponding row is switched on. In this state, when a data voltage is set on the data line DL, the data voltage is stored in the storage capacitor 3, the driver TFT 2 allows a current corresponding to the data voltage to flow from the power supply line PL through the organic EL element 4, and light is emitted corresponding to the data voltage.

As shown in the figure by a bold line, a sealing portion 18 is formed at the periphery in a rectangular frame shape. In particular, the sealing portion 18 is also formed above the terminal portion. Because the conductor of the terminal portion 16 at positions corresponding to the sealing portion 18 is formed of a transparent conductor such as ITO and IZO as described above, in these positions also, the laser light can transmit through the EL substrate 10.

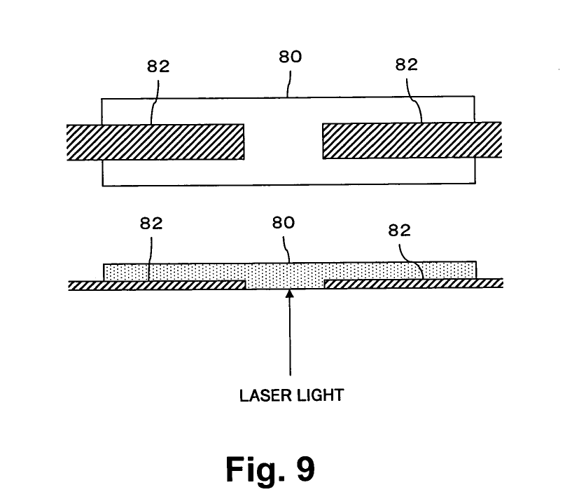

FIG. 9 exemplifies a structure at the terminal portion 16. In this configuration, only the conductor portion 80 through which laser is to transmit is formed of ITO and the other conductor portions 82 are formed of aluminum. More specifically, a laser transmissive portion of the conductor portion 82 made of aluminum is cut and a conductor portion 80 made of ITO is formed covering this portion to maintain the electrical connection.

In the foregoing description, the laser transmissive portion is provided in the terminal portion 16. It is also possible to form a part of a line portion to the terminal portion by a transparent conductor such as ITO to realize a laser transmissive portion.

The present invention is not limited to the configuration described above, as long as a configuration allows transmission of laser light through and heating of a nontransparent portion of the sealing substrate 12 in the line portion such as a terminal portion 16 on the EL substrate 10. For example, it is also possible to form a metal line with a mesh shape to allow laser to partially transmit through or to reduce the thickness to realize a semitransparent structure.

1. A manufacturing method of a display panel comprising a pixel substrate having a display region in which a plurality of display pixels are formed in a matrix form and a peripheral region surrounding the display region and a sealing substrate disposed to oppose the pixel substrate with a predetermined gap therebetween, wherein
a first one of the pixel substrate and the sealing substrate is formed of a material which allows laser to transmit and a second one of the pixel substrate and the sealing substrate has, on its peripheral region, an absorbing structure region which absorbs laser;
the absorbing structure region on the second substrate is heated by irradiating the absorbing structure region on the second substrate with laser through a peripheral region of the first substrate; and
with the heating, the absorbing structure region on the second substrate is elevated toward the first substrate so that the pixel substrate and the sealing substrate are sealed by welding at the peripheral portion to air-tightly close the space sandwiched between the substrates.

2. A manufacturing method of a display panel according to claim 1, wherein
the absorbing structure region on the second substrate is formed by doping a nontransparent material to the second substrate.

3. A manufacturing method of a display panel according to claim 1, wherein
the absorbing region on the second substrate is formed by forming a groove on the second substrate and forming a film of a nontransparent material in the groove through vacuum evaporation, sputtering, CVD, or coating.

4. A manufacturing method of a display panel according to claim 1, wherein
the material which allows laser to transmit is glass or a resin film.

5. A manufacturing method of a display panel according to claim 1, wherein
the nontransparent material is a metal.

6. A manufacturing method of a display panel according to claim 1, wherein
a black matrix which is formed of a material identical to that of the absorbing structure region is formed in a region of the sealing substrate corresponding to a boundary of pixel regions on the pixel substrate.

7. A display panel comprising:
a pixel substrate made of a material which allows laser to transmit and having a display region in which a plurality of display pixels are formed in a matrix form and a peripheral region surrounding the display region;
a sealing substrate placed to oppose the pixel substrate with a predetermined gap therebetween and which is transparent in a portion made of a material which allows laser to transmit and corresponding to the display region of the pixel substrate, wherein an absorbing structure region which absorbs laser is formed in a portion opposing the peripheral region of the pixel substrate; and
a sealing portion which seals peripheral portions of the pixel substrate and the sealing substrate to air-tightly close a space sandwiched by the substrates, wherein
a portion of the pixel substrate corresponding to the sealing portion is transparent, the sealing portion is formed by irradiating the absorbing structure region of the sealing substrate with laser to elevate the absorbing structure region, and a portion of the sealing substrate corresponding to the display region of the pixel substrate is transparent.

8. A display panel according to claim 7, wherein
the absorbing structure region on the sealing substrate is formed by doping a nontransparent material to the sealing substrate.

9. A display panel according to claim 7, wherein
the absorbing structure region on the sealing substrate is formed by forming a groove on the sealing substrate and forming a film of a nontransparent material in the groove through vacuum evaporation, sputtering, CVD, or coating.

10. A display panel according to claim 7, wherein
the material which allows laser to transmit is glass or a resin film.

11. A display panel according to claim 7, wherein
the nontransparent material is a metal.

12. A display panel according to claim 7, wherein
a black matrix formed of a material identical to that of the absorbing structure region is formed in a region of the sealing substrate corresponding to a boundary of pixel regions on the pixel substrate.

13. A display panel comprising:
a pixel substrate made of a material which allows light to transmit and having a display region in which a plurality of display pixels are formed in a matrix form and a peripheral region surrounding the display region;
a sealing substrate placed to oppose the pixel substrate with a predetermined gap therebetween and which is transparent in a portion, made of a material which allows light to transmit and corresponding to the display region of the pixel substrate; and
a sealing portion which seals peripheral portions of the pixel substrate and the sealing substrate to air-tightly close a space surrounded by the substrates, wherein
a black matrix formed by doping a nontransparent material to a material of the substrate in a region corresponding to a boundary of pixels in the display region is formed in a portion of the sealing substrate corresponding to the display region of the pixel substrate.

14. A display panel according to claim 13, wherein
the nontransparent material is a metal.
